(19) United States
(12) Patent Application Publication
(10) Pub. No.: US 2026/0344293 A1
(43) Pub. Date: Oct. 29, 2026

(54) MEMS DEVICE WITH IMPROVED ADHESION OF A PASSIVATION REGION TO A CONDUCTIVE REGION

(71) Applicant: STMicroelectronics International N.V., Geneva (CH)

(72) Inventors: Sonia COSTANTINI, Missaglia (IT); Irene MARTINI, Bergamo (IT)

(73) Assignee: STMicroelectronics International N.V., Geneva (CH)

(21) Appl. No.: 19/632,872

(22) Filed: Mar. 30, 2026

(30) Foreign Application Priority Data
Mar. 31, 2025 (IT) 102025000006732

(51) Int. Cl. H10N 30/88; H10N 30/02; H10N 30/05; H10N 30/067; H10N 30/50; H10N 30/87

(52) U.S. Cl. CPC H10N 30/883; H10N 30/02; H10N 30/05; H10N 30/067; H10N 30/501; H10N 30/871

(57) ABSTRACT

A MEMS device includes a semiconductor body having top and bottom surfaces, opposite to each other along a first axis. The top surface has a first zone and a second zone, lateral to each other orthogonally to the first axis. A first conductive region extends on the first zone of the top surface and has a respective top surface that is opposite to the semiconductor body along the first axis and is made of platinum. A passivation region made of silicon oxynitride (SiON), silicon nitride (SiN), or silicon oxide (SiO)includes a first portion, extending on the second zone of the top surface of the semiconductor body, and a second portion, extending on the first conductive region. The first portion has a first thickness along the first axis and the second portion has a second thickness along the first axis, the second thickness greater than the first thickness.

### PRIORITY CLAIM

This application claims the priority benefit of Italian Application for Patent No. 102025000006732 filed on Mar. 31, 2025, the content of which is hereby incorporated by reference in its entirety to the maximum extent allowable by law.

### TECHNICAL FIELD

This disclosure relates to a microelectromechanical systems (MEMS) device with improved adhesion of a passivation region to a conductive region. In particular, it relates to the device of the MEMS type and to a manufacturing process for the device.

### BACKGROUND

As is known, the production of electronic-type devices, in particular devices manufactured using MEMS technology, often exploits the formation of a passivation layer on a metal layer.

The passivation layer, for example formed of insulating material such as SiN, allows chemical stabilization and electrical and mechanical protection of the underlying surfaces made of semiconductor material and especially of metal layers. The latter are, for example, used as bottom electrodes (BEs) in piezoelectric structures of devices.

However, during the manufacture of devices according to currently known process flows, a random and localized lift-off of the passivation layer from the top surface of the metal layers has been observed when the metal layers are formed of platinum (Pt).

This poor adhesion is related to the use, during the manufacturing of the device, of lithographic techniques based on photoresin to pattern the metal layer before depositing the passivation layer. The use of photoresin leads to the formation of residues on the metal layer, which interpose between the passivation material and the platinum of the metal layer.

The resulting deformation of the passivation layer (e.g., the formation of bubbles at the interface between the passivation layer and the metal layer) significantly degrades the operation of the device, as it may reduce its reliability, for example by leading to accelerated degradation of the improperly passivated piezoelectric stack, by causing cracking of the layers during device operation, or by potentially allowing humidity or impurities to enter this interface.

The main cause of the formation of these residues at the interface during the manufacturing of the device is related to the particular sequence of process steps typically used.

In fact, platinum is a commonly used material in MEMS products, and it is common to find platinum layers used as bottom electrodes in most piezoelectric structures. However, this layer arrangement is critical due to the generation, during the etching step of the metal layer performed through the photoresin mask, of non-volatile compounds that deposit on the metal layer as re-sputtered material.

Furthermore, the photoresin shows significant adhesion to the platinum surface, making it difficult to remove the mask from the metal layer. In addition, the manufacturing process may also require additional heating treatments of the photoresin (e.g., thermal stabilization of the photoresin), further increasing the adhesion phenomenon.

With the current manufacturing process flow, reworking and additional cleaning treatments of the photoresin may be required, resulting in an increase in the number of steps and in the complexity and cost of the manufacturing process.

Furthermore, standard cleaning techniques, normally used to remove the photoresin after etching or to rework the mask (e.g., removing and re-placing the mask), have proven ineffective in completely cleaning the platinum surface and thus are unable to avoid the lift-off of the passivation layer in successive manufacturing steps.

There is a need to provide a device and a manufacturing process that overcome the drawbacks of the prior art.

### SUMMARY

A microelectromechanical system device is provided that has improved adhesion between a conductive region and an overlying passivation region. The device has a semiconductor body made of semiconductor material with a top surface and a bottom surface arranged opposite one another along a first axis. The top surface of the semiconductor body has a first zone and a second zone that are laterally offset from one another in a direction orthogonal to the first axis. A first conductive region extends on the first zone of the top surface of the semiconductor body and has a top surface facing away from the semiconductor body along the first axis. The first conductive region has platinum at the top surface.

A passivation region made of silicon oxynitride (SiON), silicon nitride (SiN), or silicon oxide (SiO) is arranged on the semiconductor body and the first conductive region. The passivation region has a first portion that extends on the second zone of the top surface of the semiconductor body and a second portion that extends on the first conductive region. The first portion has a first thickness measured along the first axis, and the second portion has a second thickness measured along the first axis, with the second thickness greater than the first thickness. In certain embodiments, the passivation region has a first passivation sub region that extends on the first conductive region and a second passivation sub region that extends on the second zone of the semiconductor body and on the first passivation sub region, such that the increased thickness over the first conductive region is obtained without direct interaction between a lithographic mask and the platinum surface.

In some implementations, the device has a piezoelectric stack with at least one piezoelectric structure that has the first conductive region, a piezoelectric region arranged on part of the first conductive region, and a second conductive region arranged on the piezoelectric region. The first passivation sub region extends on a zone of the first conductive region that is not covered by the piezoelectric region and also extends on the second conductive region. In further implementations, the piezoelectric stack has multiple piezoelectric structures with corresponding conductive regions and piezoelectric regions arranged in succession along the first axis, with the passivation region having multiple passivation sub regions that define portions of increasing thickness over underlying conductive regions.

A method for manufacturing a microelectromechanical system device is also provided. The method includes forming a conductive layer made of platinum on a semiconductor body, forming a first passivating layer made of silicon oxynitride (SiON), silicon nitride (SiN), or silicon oxide (SiO) on the conductive layer, selectively removing a portion of the first passivating layer to define a first passivation sub region, and patterning the conductive layer using the first passivation sub region as a mask. A second passivating layer made of silicon oxynitride (SiON), silicon nitride (SiN), or silicon oxide (SiO) is then formed on the first passivation sub region and on an exposed portion of the semiconductor body, such that a passivation region is obtained with a greater thickness over the first conductive region than over the semiconductor body. This approach reduces contamination of the platinum surface and improves adhesion and reliability of the passivation region in the finished device.

### BRIEF DESCRIPTION OF THE DRAWINGS

For a better understanding, a preferred embodiment is now described, purely by way of non-limiting example, with reference to the attached drawings, wherein:

FIG. 1 is a schematic cross-sectional view of a device, according to one embodiment;

FIGS. 2A–2F are schematic cross-sectional views of respective steps of a manufacturing process of the device of FIG. 1, according to one embodiment;

FIG. 3 is a schematic cross-sectional view of the device, according to a different embodiment;

FIGS. 4A–4F are schematic cross-sectional views of respective steps of a manufacturing process of the device of FIG. 3, according to one embodiment;

FIG. 5 is a schematic cross-sectional view of the device, according to a different embodiment;

FIGS. 6A–6I are schematic cross-sectional views of respective steps of a manufacturing process of the device of FIG. 5, according to one embodiment;

FIG. 7 is a schematic cross-sectional view of the device, according to one embodiment; and

FIGS. 8A–8F are schematic cross-sectional views of respective steps of a manufacturing process of the device of FIG. 7, according to one embodiment.

### DETAILED DESCRIPTION =

In particular, the Figures are shown with reference to a triaxial Cartesian system defined by an X-axis, a Y-axis, and a Z-axis, orthogonal to each other.

In the following description, elements common to the different embodiments are indicated with the same reference numbers.

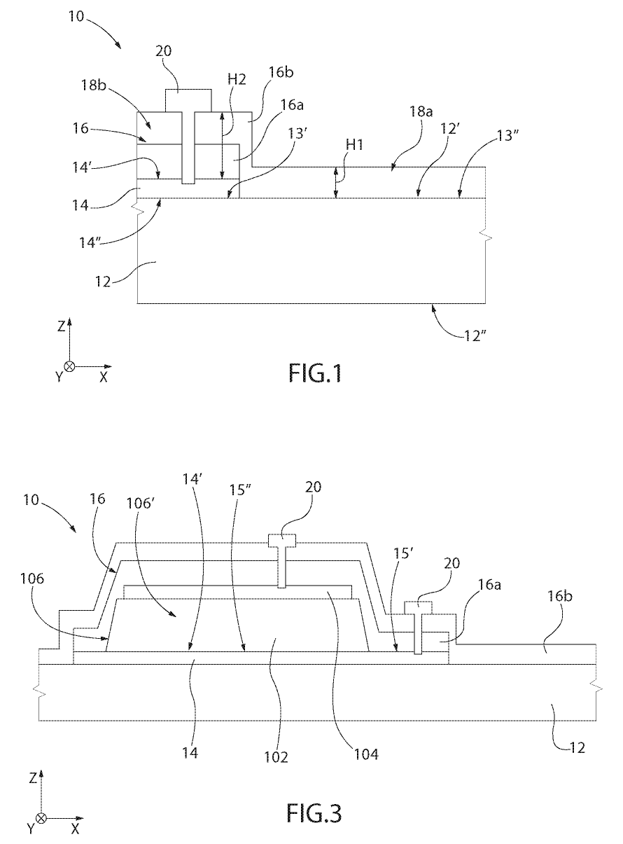

FIG. 1 shows a device 10, in particular of the MEMS type.

FIG. 1 shows only the elements of the device 10 that are useful for understanding this disclosure. Accordingly, other elements may obviously be present, although not shown here nor described in detail below since they are known to those of skill in the art and not relevant.

FIG. 1 shows the device 10 in cross-section in an XZ plane defined by the axes X and Z.

The device 10 comprises a semiconductor body 12, comprising semiconductor material such as silicon.

The semiconductor body 12 is shown here as a monolithic substrate made of semiconductor material; however, the semiconductor body 12 may also comprise a plurality of layers or regions of different materials (e.g., a stack of layers made of semiconductor material such as polysilicon and, for example, epipoly, and/or insulating and/or conductive material).

The semiconductor body 12 has a top surface 12’ and a bottom surface 12”, opposite to each other along the Z-axis.

The device 10 also comprises a conductive region 14 of conductive material, in particular metal material, and more specifically platinum.

The conductive region 14 has a top surface 14’ and a bottom surface 14”, opposite to each other along the Z-axis.

The conductive region 14 extends on the semiconductor body 12, in particular on part of the top surface 12’.

In detail, the conductive region 14 extends on a first zone 13’ of the top surface 12' of the semiconductor body 12. A second zone 13” of the top surface 12' of the semiconductor body 12, lateral to the first zone 13’ for example along the X-axis, is not covered by the conductive region 14.

For example, the bottom surface 14” of the conductive region 14 is in contact with the top surface 12’ of the semiconductor body 12.

For purely illustrative and non-limiting purposes, the conductive region 14 forms an electrode of the device 10.

The device 10 also comprises a passivation region 16 made of passivating material, in particular made of insulating material such as silicon oxynitride (SiON), silicon nitride (SiN), or silicon oxide (SiO).

The passivation region 16 extends on the conductive region 14 and on the part of the semiconductor body 12 that is exposed by the conductive region 14. In other words, the passivation region 16 extends on the top surface 14’ of the conductive region 14 and on the second zone 13” of the top surface 12’ of the semiconductor body 12.

More in detail, the passivation region 16 has a first portion 18a, which extends on the second zone 13″ of the semiconductor body 12 (i.e., which is not superimposed on the conductive region 14 along the Z-axis but is lateral to the conductive region 14 along the X-axis), and a second portion 18b, which extends on the conductive region 14 and is therefore vertically aligned (i.e., aligned along the Z-axis) with the first zone 13’ of the semiconductor body 12.

The first portion 18a has a first thickness H1 along the Z-axis direction, while the second portion 18b has a second thickness H2 along the Z-axis direction. The second thickness H2 is greater than the first thickness H1.

For example, the first thickness H1 and the second thickness H2 are average thicknesses measured along the Z-axis of the respective portions 18a and 18b.

For illustrative and non-limiting purposes, the first thickness H1 is comprised between about 100 nm and about 200 nm and is, for example, equal to about 150 nm, while the second thickness H2 is comprised between about 200 nm and about 400 nm and is, for example, equal to about 300 nm. In other words, a ratio H2/H1 between the second thickness H2 and the first thickness H1 is comprised between about 1.5 and about 3 and is, for example, equal to about 2.

In particular, the passivation region 16 includes a first passivation sub-region 16a and a second passivation sub-region 16b. The first passivation sub-region 16a is defined by a layer made of passivating material that extends on the conductive region 14 without covering the second zone 13″ of the semiconductor body 12, while the second passivation sub-region 16b is defined by a respective layer made of passivating material that extends both on the second zone 13″ of the semiconductor body 12 and on the first passivation sub-region 16a. In other words, the second passivation sub-region 16b uniformly covers both the semiconductor body 12 and the conductive region 14.

Furthermore, a top surface (not shown) of the passivation region 16 is defined by the top surface of the second passivation sub-region 16b, while a bottom surface (not shown) of the passivation region 16 is defined by the combination of a bottom surface of the second passivation sub-region 16b and a bottom surface of the first passivation sub-region 16a.

Accordingly, the first portion 18a of the passivation region 16 includes only the part of the second passivation sub-region 16b that extends on the second zone 13″ of the semiconductor body 12, while the second portion 18b of the passivation region 16 includes both the first passivation sub-region 16a and the part of the second passivation sub-region 16b that extends on the first passivation sub-region 16a.

Therefore, the difference between the second thickness H2 and the first thickness H1 is equal to the thickness (not shown and measured along the Z‑axis) of the first passivation sub-region 16a.

Optionally, the device 10 may comprise further elements or components not described in detail herein, such as a conductive via 20 that extends along the Z‑axis through the second portion 18b, starting from the top surface down to the bottom surface of the passivation region 16, in such a way as to be in direct physical contact with the underlying conductive region 14 to allow its electrical contact from the outside of the device 10.

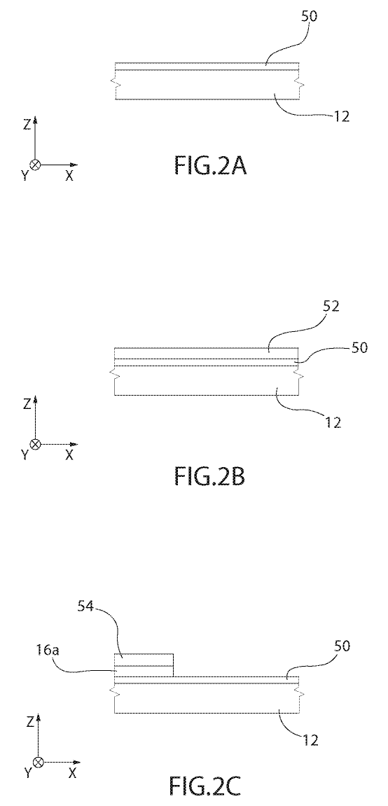

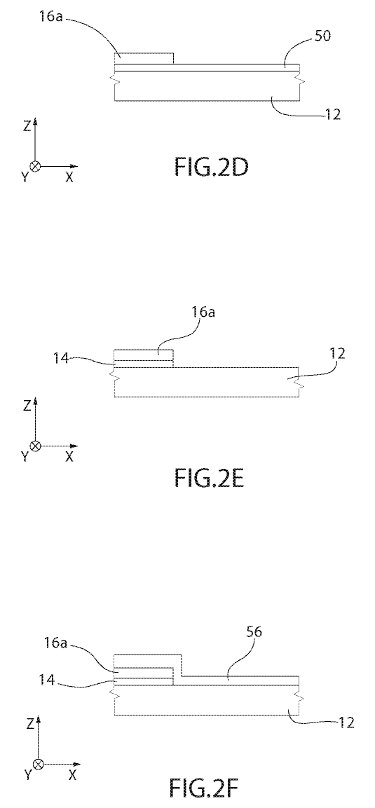

FIGS. 2A–2F show, in a lateral sectional view in the XZ plane, the device 10 during respective steps of a manufacturing process used to manufacture the device 10.

The manufacturing steps shown are successive to each other and relate only to the formation of the parts and elements of the device 10 that are useful for the purposes of understanding. As is evident, other manufacturing steps may be present, among those shown and/or before and after those shown, to provide parts or components of the device 10 that are not described in detail here.

In particular, in FIG. 2A, a conductive layer 50 is formed on a semiconductor body.

The semiconductor body defines the semiconductor body 12 previously described. Accordingly, it is not described again in detail here and is indicated with the same reference number.

The conductive layer 50 is of conductive material, in particular metal material, and more specifically platinum.

For illustrative and non-limiting purposes, the conductive layer 50 has a thickness along the Z‑axis that is comprised between about 80 nm and about 200 nm and is, for example, equal to about 100 nm.

The conductive layer 50 is formed uniformly on the top surface 12' of the semiconductor body 12, for example by deposition (e.g., Physical Vapor Deposition, PVD).

In detail, the conductive layer 50 is intended to form the conductive region 14, as described in greater detail below.

In FIG. 2B, a first passivating layer 52 is formed on the conductive layer 50.

The first passivating layer 52 is made of passivating material, in particular insulating material such as silicon oxynitride (SiON), silicon nitride (SiN), or silicon oxide (SiO) .

For illustrative and non-limiting purposes, the first passivating layer 52 has a thickness along the Z‑axis that is comprised between about 100 nm and about 200 nm and is, for example, equal to about 150 nm.

The first passivating layer 52 is formed uniformly on the top surface of the conductive layer 50, for example by deposition (e.g., Plasma‑Enhanced Chemical Vapor Deposition (PECVD) or Atomic Layer Deposition (ALD)).

In detail, the first passivating layer 52 is intended to form the first passivation sub-region 16a, as described in greater detail below.

In FIG. 2C, a lithographic mask 54 is formed on the first passivating layer 52, in such a way as to cover a first zone of the first passivating layer 52, which is intended to form the first passivation sub-region 16a, and to expose a second zone of the first passivating layer 52, lateral to the first zone, for example along the X‑axis, and intended to be removed.

In detail, the lithographic mask 54 is superimposed along the Z‑axis on what is intended to become the first zone 13’ of the top surface 12’ of the semiconductor body 12.

The lithographic mask 54 is of photoresin and is formed by photolithographic techniques.

For illustrative and non-limiting purposes, the lithographic mask 54 has a thickness along the Z‑axis that is comprised between about 1 µm and about 3 µm and is, for example, equal to about 2 µm.

Furthermore, in FIG. 2C, the part of the first passivating layer 52 that is exposed by the lithographic mask 54 is removed. The remaining part of the first passivating layer 52, covered by the lithographic mask 54, defines the first passivation sub-region 16a.

The first passivating layer 52 is partially removed by etching, such as dry or wet etching (e.g., using etching chemistries such as CF₃, or “buffered oxide etch”).

This etching step then exposes a zone of the conductive layer 50 that is superimposed along the Z‑axis on what is intended to become the second zone 13” of the top surface 12’ of the semiconductor body 12.

In FIG. 2D, the lithographic mask 54 is removed from the first passivation sub-region 16a.

In FIG. 2E, the part of the conductive layer 50 that is exposed by the first passivation sub-region 16a is removed, with the first passivation sub-region 16a therefore being used as a mask. The remaining part of the conductive layer 50, covered by the first passivation sub-region 16a, defines the conductive region 14.

The conductive layer 50 is partially removed by etching, for example dry or wet etching.

This etching step then exposes the second zone 13” of the top surface 12’ of the semiconductor body 12.

In FIG. 2F, a second passivating layer 56 is formed on the first passivation sub-region 16a and on the second zone 13” of the top surface 12’ of the semiconductor body 12.

The second passivating layer 56 is made of passivating material, in particular insulating material such as silicon oxynitride (SiON), silicon nitride (SiN), or silicon oxide (SiO).

For illustrative and non-limiting purposes, the second passivating layer 56 has a thickness along the Z‑axis that is comprised between about 100 nm and about 200 nm and is, for example, equal to about 150 nm.

The second passivating layer 56 is formed uniformly on the second zone 13” of the top surface 12’ of the semiconductor body 12 and on the top surface of the first passivation sub-region 16a, for example by deposition (e.g., Plasma‑Enhanced Chemical Vapor Deposition (PECVD) or Atomic Layer Deposition (ALD)).

In detail, the second passivating layer 56 forms the second passivation sub-region 16b that, together with the first passivation sub-region 16a, forms the passivation region 16.

Further manufacturing steps may follow, as is evident. For example, steps may follow to form the conductive via 20, to form further parts (not shown) of the device 10, to package the device 10, etc. Nevertheless, these steps are not described in detail here.

FIG. 3 shows the device 10 in a possible application implementation thereof.

In FIG. 3, for illustrative and non-limiting purposes, the device 10 may be used for laser beam scanning, for moving micro-lenses, in microphones or speakers, in inkjet print heads, or in autofocus lenses.

The parts of the device 10 of FIG. 3 that are common to what has been previously described are not repeated here again.

In detail, the conductive region 14 is here also referred to as the first conductive region (or bottom conductive region) 14.

In addition, the device 10 of FIG. 3 comprises a first piezoelectric region 102 and a second conductive region (or top conductive region) 104.

The second conductive region 104 is of conductive material, in particular of metal (such as platinum, aluminum, copper, gold) or metal oxide or combinations thereof. For example, the second conductive region 104 has a thickness along the Z‑axis similar to that of the first conductive region 14.

The first piezoelectric region 102 is of piezoelectric material (such as PZT, AlN, for example doped with Sc, KNN) and may be monolithic or may be defined by a stack of different piezoelectric materials. For illustrative and non-limiting purposes, the first piezoelectric region 102 has a thickness along the Z‑axis that is comprised between about 100 nm and about 3 µm and is, for example, equal to about 2 µm.

The first conductive region 14, the first piezoelectric region 102, and the second conductive region 104 are superimposed on each other in succession along the Z‑axis, in such a way as to define together a first piezoelectric structure 106’ of a piezoelectric stack 106. In detail, the first piezoelectric region 102 extends on the first conductive region 14 and the second conductive region 104 extends on the first piezoelectric region 102.

In this case, the passivation region 16 extends on the piezoelectric stack 106, to cover it and insulate it from the external environment.

In detail, a first zone 15’ of the top surface 14’ of the first conductive region 14 is exposed by the first piezoelectric region 102 and is instead covered by the first passivation sub-region 16a, while a second zone 15” of the top surface 14’ of the first conductive region 14 is covered by the first piezoelectric region 102. For example, the first conductive region 14 has a central part defining the second zone 15” and two lateral parts defining the first zone 15’, that extend laterally to the central part along the X‑axis (from respective opposite sides of the latter along the X‑axis). Accordingly, FIG. 1 shows in detail one of these lateral parts, for example the right lateral part.

Similarly to what has been previously described, other elements may be present although not described here in detail. For example, the device 10 may comprise a conductive via 20 for each conductive region 14, 104.

In FIG. 3, the first conductive region 14 defines a bottom electrode of the device 10, while the second conductive region 104 defines a top electrode of the device 10.

In use, these electrodes may be biased in a known manner to control or sense the deformation of the piezoelectric region 102.

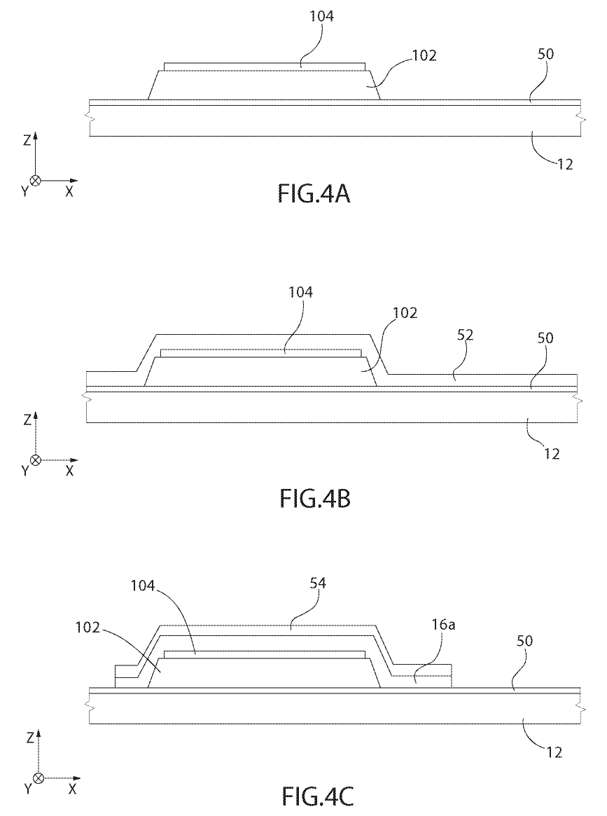

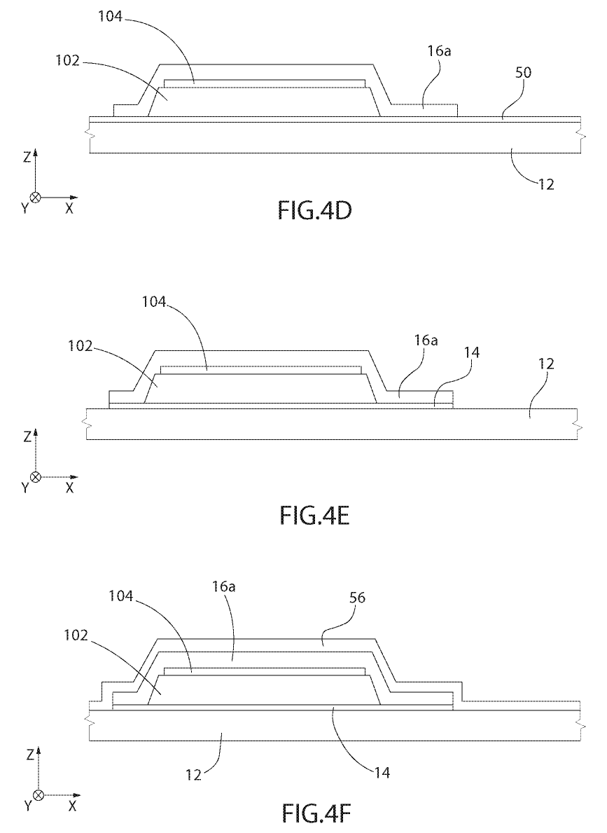

FIGS. 4A-4G show, in a lateral sectional view in the XZ plane, the device 10 of FIG. 3 in respective steps of the manufacturing process.

The manufacturing steps shown are successive to each other and relate only to the formation of the parts and elements of the device 10 that are useful for the purposes of understanding. As is evident, other manufacturing steps may be present, among those shown and/or before and after those shown, to provide parts or components of the device 10 that are not described in detail here.

In particular, in FIG. 4A, the conductive layer 50 is formed on the semiconductor body 12, similarly to what has been described with reference to FIG. 2A.

Furthermore, in FIG. 4A, the first piezoelectric region 102 and the second conductive region 104 are also formed, in succession to each other, on part of the conductive layer 50.

In FIG. 4B, the first passivating layer 52 is formed on the conductive layer 50, similarly to what has been described with reference to FIG. 2B.

Furthermore, the first passivating layer 52 is also formed on the first piezoelectric region 102 and the second conductive region 104, to uniformly cover the structure of FIG. 4A.

In FIG. 4C, the lithographic mask 54 is formed on the first passivating layer 52, similarly to what has been described with reference to FIG. 2C.

In particular, the lithographic mask 54 is superimposed along the Z‑axis on the first piezoelectric region 102, on the second conductive region 104, and on what will become the lateral parts of the first conductive region 14.

Furthermore, in FIG. 4C, the part of the first passivating layer 52 that is exposed by the lithographic mask 54 is removed, similarly to what has been described with reference to FIG. 2C. The remaining part of the first passivating layer 52, covered by the lithographic mask 54, defines the first passivation sub-region 16a.

In FIG. 4D, the lithographic mask 54 is removed from the first passivation sub-region 16a, similarly to what has been described with reference to FIG. 2D.

In FIG. 4E, the part of the conductive layer 50 that is exposed by the first passivation sub-region 16a is removed, with the first passivation sub-region 16a therefore being used as a mask, similarly to what has been described with reference to FIG. 2E. The remaining part of the conductive layer 50, covered by the first passivation sub-region 16a, defines the first conductive region 14.

In FIG. 4F, the second passivating layer 56 is formed on the first passivation sub-region 16a and on the second zone 13” of the top surface 12’ of the semiconductor body 12, similarly to what has been described with reference to FIG. 2F.

Further manufacturing steps of a known type may follow, as evident and therefore not described in detail.

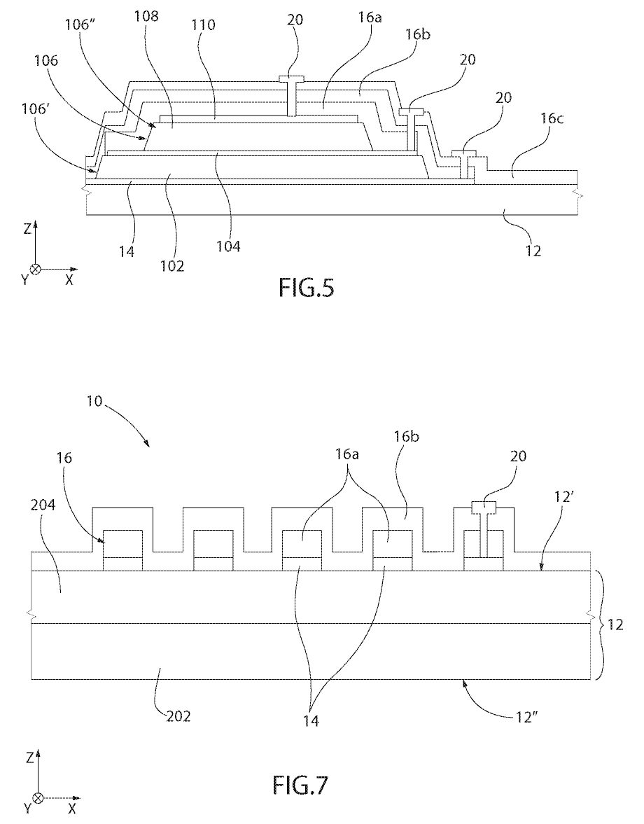

FIG. 5 shows the device 10 in a further possible application implementation thereof.

In FIG. 5, for illustrative and non-limiting purposes, the device 10 may be used for laser beam scanning, to move micro-lenses, in microphones or speakers, in inkjet print heads, or in autofocus lenses.

The device 10 of FIG. 5 is similar to the device 10 of FIG. 3; accordingly, the common parts are not described here again.

In addition to the structure of FIG. 3, the device 10 of FIG. 5 also comprises a second piezoelectric region 108 and a third conductive region 110.

The second piezoelectric region 108 and the third conductive region 110 are similar to the first piezoelectric region 102 and the second conductive region 104, respectively, and therefore are not described in detail again.

The second piezoelectric region 108 extends on the second conductive region 104, and the third conductive region 110 extends on the second piezoelectric region 108.

The second conductive region 104, the second piezoelectric region 108, and the third conductive region 110 define a second piezoelectric structure 106” of the piezoelectric stack 106, in addition to the first piezoelectric structure 106’.

Furthermore, the passivation region 16 herein also comprises a third passivation sub-region 16c. In FIG. 5, the first passivation sub-region 16a extends on the second piezoelectric region 108, on the third conductive region 110, and on zones of the second conductive region 104 that are exposed by the second piezoelectric region 108; the second passivation sub-region 16b extends on the first passivation sub-region 16a and on zones of the second conductive region 104 that are exposed by the first piezoelectric region 102; and the third passivation sub-region 16c extends on the second passivation sub-region 16b and on the zones of the semiconductor body 12 that are exposed by the first conductive region 14.

Accordingly, in this case the passivation region 16 also comprises a third portion (not shown) that extends on the first zone of the top surface of the second conductive region 104 and is defined by the first passivation sub-region 16a and by the parts of the second and third passivation sub-regions 16b and 16c that extend on the first zone of the top surface of the second conductive region 104. This third portion has, along the Z‑axis, a third thickness (not shown) that is greater than the first thickness H1 and the second thickness H2.

However, it is clear that the number of piezoelectric structures may also be greater than two (e.g., N, with N>2) and that, in this case, there will be a corresponding number of passivation sub-regions (in detail, N+1).

Similarly to what has been previously described, other elements may be present although not described here in detail. For example, the device 10 may comprise a conductive via 20 for each conductive region 14, 104, 110.

In FIG. 5, the first conductive region 14 defines a bottom electrode of the device 10, the second conductive region 104 defines a middle electrode of the device 10, and the third conductive region 110 defines a top electrode of the device 10.

In use, these electrodes may be biased in a known manner to control or sense the deformation of the piezoelectric regions 102 and 108.

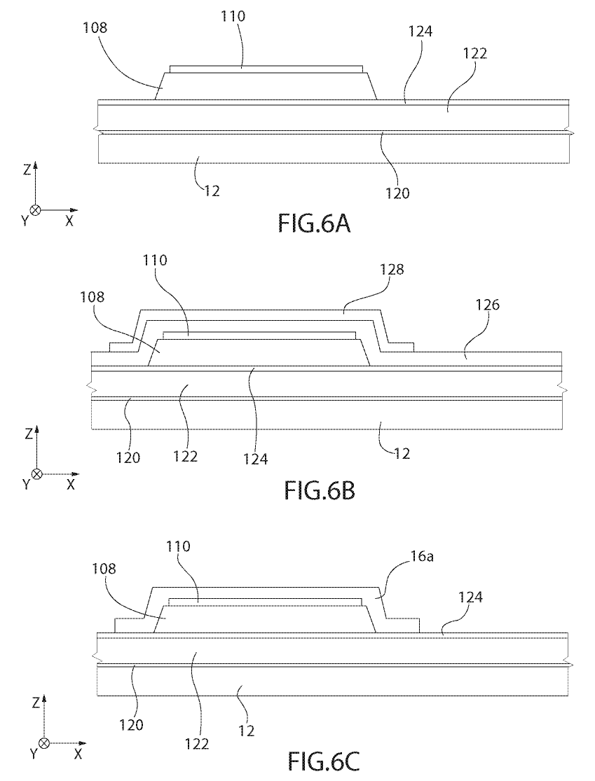

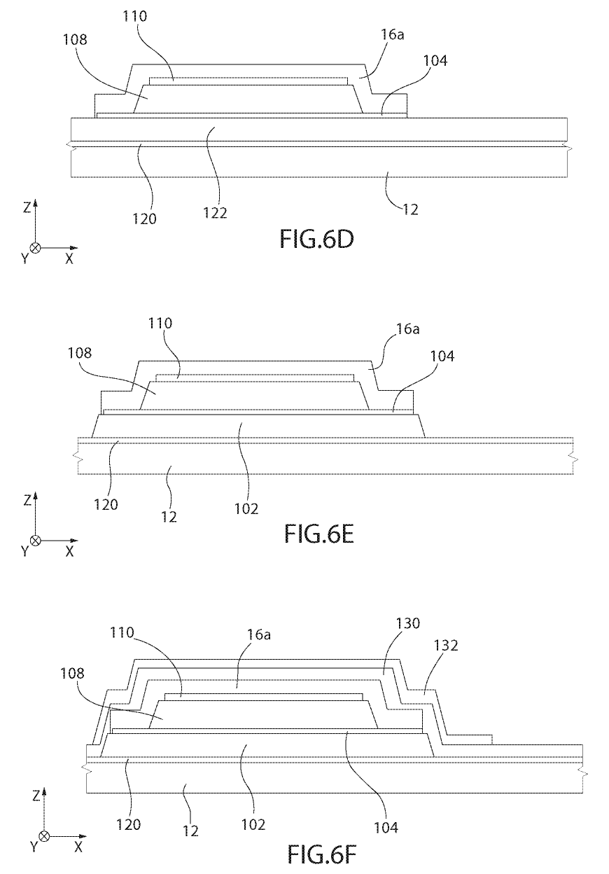

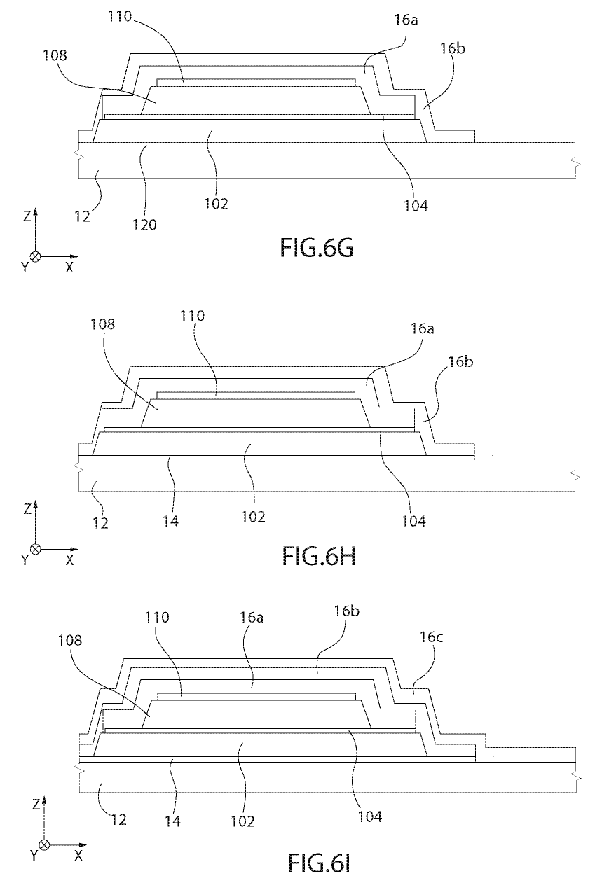

FIGS. 6A–6I show, in a lateral sectional view in the XZ plane, the device 10 of FIG. 5 in respective steps of the manufacturing process.

The manufacturing steps shown are successive to each other and relate only to the formation of the parts and elements of the device 10 that are useful for the purposes of understanding. As is evident, other manufacturing steps may be present, among those shown and/or before and after those shown, to provide parts or components of the device 10 that are not described here in detail.

In particular, in FIG. 6A, a first conductive layer 120 is formed on the semiconductor body 12, similarly to what has been described with reference to FIG. 2A as regards the conductive layer 50.

Furthermore, in FIG. 6A, a first piezoelectric layer 122, a second conductive layer 124, the second piezoelectric region 108, and the third conductive region 110 are also formed in succession. The first piezoelectric layer 122 extends uniformly on the first conductive layer 120, the second conductive layer 124 extends uniformly on the first piezoelectric layer 122, and the second piezoelectric region 108 and the third conductive region 110 extend on part of the second conductive layer 124.

In FIG. 6B, a first passivating layer 126 is formed on the second conductive layer 124, similarly to what has been described with reference to FIG. 2B as regards the first passivating layer 52.

Furthermore, the first passivating layer 126 is also formed on the second piezoelectric region 108 and the third conductive region 110, to uniformly cover the structure of FIG. 6A.

Furthermore, in FIG. 6B, a first lithographic mask 128 is formed on the first passivating layer 126, similarly to what has been described with reference to FIG. 2C as regards the lithographic mask 54.

In particular, the first lithographic mask 128 is superimposed along the Z‑axis on the second piezoelectric region 108, on the third conductive region 110, and on the part of the second conductive layer 124 that will become the second conductive region 104.

In FIG. 6C, the part of the first passivating layer 126 that is exposed by the first lithographic mask 128 is removed, similarly to what has been described with reference to FIG. 2C. The remaining part of the first passivating layer 126, covered by the first lithographic mask 128, defines the first passivation sub-region 16a.

Furthermore, in FIG. 6C, the first lithographic mask 128 is removed from the first passivation sub-region 16a, similarly to what has been described with reference to FIG. 2D.

In FIG. 6D, the part of the second conductive layer 124 that is exposed by the first passivation sub-region 16a is removed, with the first passivation sub-region 16a therefore being used as a mask, similarly to what has been described with reference to FIG. 2E. The remaining part of the second conductive layer 124, covered by the first passivation sub-region 16a, defines the second conductive region 104.

In FIG. 6E, the part of the first piezoelectric layer 122 that is exposed by the second conductive region 104 and thus by the first passivation sub-region 16a is removed, with the first passivation sub-region 16a therefore again being used as a mask. The remaining part of the first piezoelectric layer 122, covered by the first passivation sub-region 16a, defines the first piezoelectric region 102.

In FIG. 6F, a second passivating layer 130 is formed on the first conductive layer 120, similarly to what has been described with reference to FIG. 6B as regards the first passivating layer 126.

Furthermore, the second passivating layer 130 is also formed on the first passivating layer 126, to uniformly cover the structure of FIG. 6E.

Furthermore, in FIG. 6F, a second lithographic mask 132 is formed on the second passivating layer 130, similarly to what has been described with reference to FIG. 6B as regards the first lithographic mask 128.

In particular, the second lithographic mask 132 is superimposed along the Z-axis on the first passivation sub-region 16a and on the part of the first conductive layer 120 that will become the first conductive region 14.

In FIG. 6G, the part of the second passivating layer 130 that is exposed by the second lithographic mask 132 is removed, similarly to what has been described with reference to FIG. 6C. The remaining part of the second passivating layer 130, covered by the second lithographic mask 132, defines the second passivation sub-region 16b.

Furthermore, in FIG. 6G, the second lithographic mask 132 is removed from the second passivation sub-region 16b, similarly to what has been described with reference to FIG. 6C.

In FIG. 6H, the part of the first conductive layer 120 that is exposed by the second passivation sub-region 16b is removed, with the second passivation sub-region 16b therefore being used as a mask, similarly to what has been described with reference to FIG. 6E as regards the first passivation sub-region 16a. The remaining part of the first conductive layer 120, covered by the second passivation sub-region 16b, defines the first conductive region 14.

In FIG. 6I, a third passivating layer is formed on the second passivation sub-region 16b and on the exposed part of the top surface 12’ of the semiconductor body 12, similarly to what has been described with reference to FIG. 2F as regards the second passivating layer 56. The third passivating layer defines the third passivation sub-region 16c.

Further known manufacturing steps may follow, as is evident and therefore not described in detail.

FIG. 7 shows the device 10 in a possible further application implementation thereof.

In FIG. 7, for illustrative and non-limiting purposes, the device 10 may be used as a temperature sensor.

In FIG. 7, the device 10 has the semiconductor body 12 that comprises a semiconductive body region 202 and an insulating body region 204, extending on the semiconductive body region 202 along the Z‑axis.

The semiconductive body region 202 is made of semiconductor material, here for example silicon, and the insulating body region 204 is made of passivating material, in particular insulating material such as SiN or SiO.

A plurality of conductive regions 14 extend on the top surface 12’ of the semiconductor body 12, lateral to each other along the X-axis and at a distance from each other.

The respective first passivation sub-region 16a extends on each conductive region 14.

The second passivation sub-region 16b that defines, together with the first passivation sub-regions 16a, the passivation region 16, extends on the first passivation sub-regions 16a and on the zones of the top surface 12’ of the semiconductor body 12 that are exposed by the conductive regions 14.

Optionally, the device 10 of FIG. 7 may comprise further elements or components not described in detail here, such as one or more conductive vias 20.

In use, the conductive regions 14 have an electrical resistance that depends on the temperature, making it possible to use the device 10 of FIG. 7 as a sensor sensitive to temperature changes.

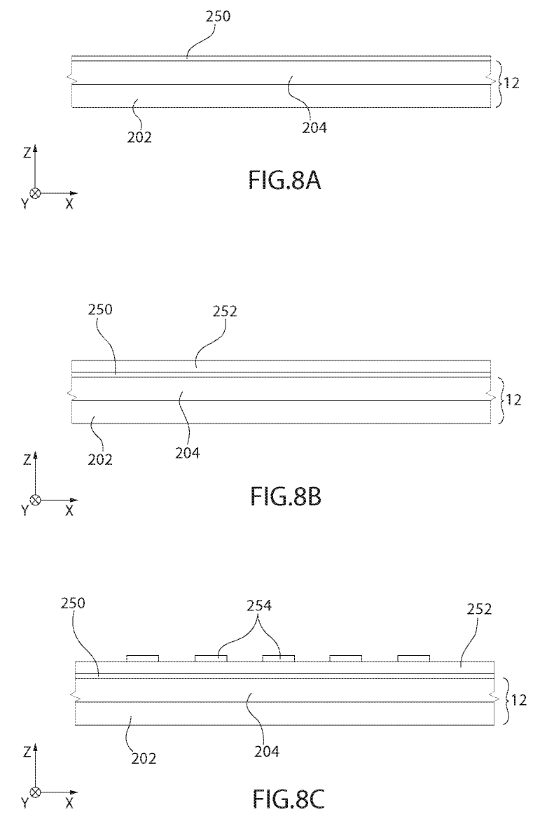

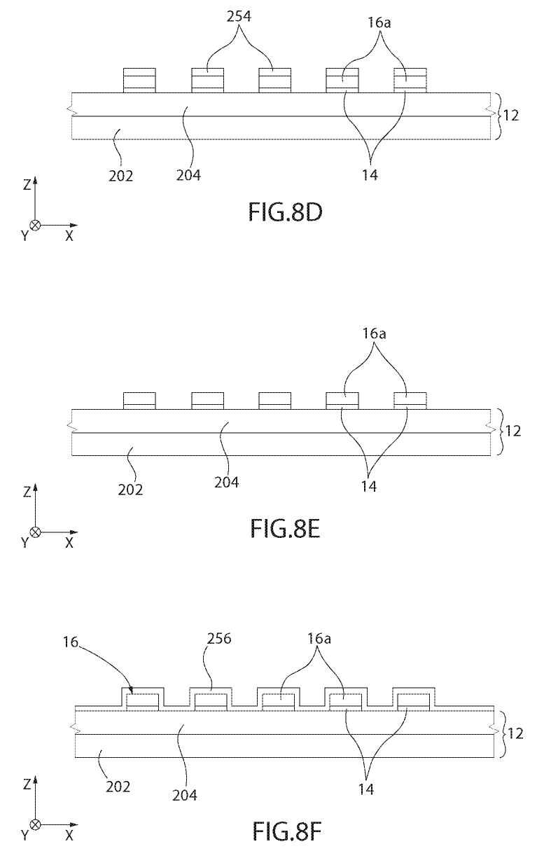

FIGS. 8A–8F show, in a lateral sectional view in the XZ plane, the device 10 of FIG. 7 in respective steps of the manufacturing process.

The manufacturing steps shown are successive to each other and relate only to the formation of the parts and elements of the device 10 of FIG. 7 that are useful for the purposes of understanding. As is evident, other manufacturing steps may be present, among those shown and/or before and after those shown, to provide parts or components of the device 10 that are not described in detail here.

In particular, in FIG. 8A, a conductive layer 250 is formed on the semiconductor body 12 (here comprising the semiconductive body region 202 and the insulating body region 204), similarly to what has been described with reference to FIG. 2A.

In FIG. 8B, a passivating layer 252 is formed on the conductive layer 250, similarly to what has been described with reference to FIG. 2B.

In FIG. 8C, a lithographic mask 254 is formed on the passivating layer 252, similarly to what has been described with reference to FIG. 2C.

In particular, the lithographic mask 254 covers regions of the passivating layer 252 that are intended to form the first passivation sub-regions 16a and leaves exposed the remaining regions of the passivating layer 252.

In FIG. 8D, the parts of the passivating layer 252 that are exposed by the lithographic mask 254 are removed, similarly to what has been described with reference to FIG. 2C. The remaining parts of the passivating layer 252, covered by the lithographic mask 254, define the first passivation sub-regions 16a.

In FIG. 8E, the lithographic mask 254 is removed from the first passivation sub-regions 16a, similarly to what has been described with reference to FIG. 2D.

Furthermore, in FIG. 8E, the parts of the conductive layer 250 that are exposed by the first passivation sub-regions 16a are removed, with the first passivation sub-regions 16a therefore being used as a mask, similarly to what has been described with reference to FIG. 2E. The remaining parts of the conductive layer 250, covered by the first passivation sub-regions 16a, define the conductive regions 14.

In FIG. 8F, a second passivating layer 256 is formed on the first passivation sub-regions 16a and on the zones of the top surface 12’ of the semiconductor body 12 that are exposed by the conductive regions 14, similarly to what has been described with reference to FIG. 2F.

Further manufacturing steps of a known type may follow, as is evident and therefore not described in detail.

From an examination of the characteristics of this disclosure, the advantages that it affords are evident.

In detail, the present manufacturing process allows the use of the first passivation sub-region 16a as a hard mask for the patterning of the conductive region 14, thus avoiding the direct interaction between the platinum of the conductive region 14 and the photoresin of the lithographic mask 54. This significantly reduces the risk of surface contamination of the platinum, thus avoiding the deformation and delamination of the passivation region 16 and therefore improving the reliability of the device 10.

This manufacturing process is versatile: this process flow may be applied to any structure that has the elements shown in FIG. 1.

This manufacturing process allows a simplified management of the production (for example, standard lithography rework may be used).

Furthermore, no additional lithographic-mask level is required.

Finally, it is clear that modifications and variations may be made to the embodiments described and illustrated herein without thereby departing from the scope of this disclosure, as defined in the attached claims.

For example, the different embodiments described may be combined with each other to provide further solutions.

Furthermore, the conductive region 14 may also not be entirely made of platinum as described so far, but may rather comprise a stack of conductive materials (in particular metal materials) different from each other with a top conductive layer made of platinum, that defines the top surface 14’ of the conductive region 14.

Furthermore, each of the passivation sub-regions may in turn be defined by a respective stack of passivating layers, made of passivating materials different from each other.

Furthermore, this manufacturing process similarly applies to any structure that comprises a conductive region 14, comprising platinum in the top surface 14’, and an overlying passivation region 16.

Furthermore, the removal of the lithographic mask 54, previously shown in FIG. 2D, may also occur after the etching of FIG. 2E and before the formation of the second passivation sub-region 16b. In this manner, the etching of the conductive layer 50 may occur using the stack of the first passivation sub-region 16a and the lithographic mask 54 as a mask. This reduces the chances of the etching damaging the first passivation sub-region 16a. This also applies similarly to the other previously described embodiments of the manufacturing process of the device 10.

1. A microelectromechanical systems (MEMS) device, comprising:
a semiconductor body comprising semiconductor material and having a top surface and a bottom surface, opposite to each other along a first axis, the top surface of the semiconductor body having a first zone and a second zone lateral to each other orthogonally to the first axis;
a first conductive region which extends on the first zone of the top surface of the semiconductor body and has a respective top surface that is opposite to the semiconductor body along the first axis and that comprises platinum; and
a passivation region made of silicon oxynitride (SiON), silicon nitride (SiN), or silicon oxide (SiO) and comprising a first portion extending on the second zone of the top surface of the semiconductor body, and a second portion extending on the first conductive region;
wherein the first portion has a first thickness along the first axis and the second portion has a second thickness along the first axis, the second thickness being greater than the first thickness.

2. The device according to claim 1:
wherein the passivation region comprises a first passivation sub-region extending on the first conductive region, and a second passivation sub-region extending in part on the second zone of the top surface of the semiconductor body and in part on the first passivation sub-region; and
wherein the first portion of the passivation region is defined by the part of the second passivation sub-region that extends on the second zone of the top surface of the semiconductor body, and the second portion of the passivation region is defined by the first passivation sub-region and the part of the second passivation sub-region that extends on the first passivation sub-region.

3. The device according to claim 2, further comprising a piezoelectric stack including at least a first piezoelectric structure defined by:
the first conductive region, wherein the top surface of the first conductive region has a respective first zone and a respective second zone lateral to each other orthogonally to the first axis;
a first piezoelectric region made of piezoelectric material and extending on the second zone of the top surface of the first conductive region; and
a second conductive region made of conductive material and extending on the first piezoelectric region;
wherein the first passivation sub-region extends on the first zone of the top surface of the first conductive region and on the second conductive region.

4. The device according to claim 1, further comprising a piezoelectric stack including at least a first piezoelectric structure and a second piezoelectric structure;
wherein the first piezoelectric structure is defined by:
the first conductive region, wherein the top surface of the first conductive region has a respective first zone and a respective second zone, lateral to each other orthogonally to the first axis;
a first piezoelectric region of piezoelectric material and extending on the second zone of the top surface of the first conductive region; and
a second conductive region of conductive material and extending on the first piezoelectric region;
wherein the second piezoelectric structure is defined by:
the second conductive region, wherein a top surface of the second conductive region has a respective first zone and a respective second zone, lateral to each other orthogonally to the first axis;
a second piezoelectric region of piezoelectric material and extending on the second zone of the top surface of the second conductive region; and
a third conductive region of conductive material and extending on the second piezoelectric region,

5. The device according to claim 4, wherein the passivation region comprises a first passivation sub-region extending on the third conductive region and on the first zone of the top surface of the second conductive region, a second passivation sub-region extending on the first passivation sub-region and on the first zone of the top surface of the first conductive region, and a third passivation sub-region extending on the second passivation sub-region and on the second zone of the top surface of the semiconductor body;
wherein the passivation region further comprises a third portion extending on the first zone of the top surface of the second conductive region and defined by the first passivation sub-region and parts of the second and third passivation sub-regions that extend on the first zone of the top surface of the second conductive region; and
wherein the third portion has a third thickness along the first axis that is greater than the first thickness and the second thickness.

6. The device according to claim 1:
wherein the semiconductor body comprises a semiconductive body region made of semiconductor material, and an insulating body region made of passivating material and extending on the semiconductive body region along the first axis; wherein the device comprises a plurality of said first conductive regions that extend laterally to each other and at a distance from each other orthogonally to the first axis; and
wherein the device comprises a plurality of said first portions and second portions, each first portion extending on a respective part of the second zone of the top surface of the semiconductor body and between two respective first conductive regions, and each second portion extending on the respective first conductive region.

7. The device according to claim 1, wherein the first conductive region is made of platinum or is defined by a stack of conductive materials comprising a top layer made of platinum that defines the top surface of the first conductive region.

8. The device according to claim 1, wherein the first thickness H1 is comprised between about 100 nm and about 200 nm and the second thickness H2 is comprised between about 200 nm and about 400 nm.

9. A method for manufacturing a microelectromechanical (MEMS) device, comprising steps of:
a) forming a conductive layer on a top surface of a semiconductor body, the semiconductor body comprising semiconductor material and having the top surface and a bottom surface, opposite to each other along a first axis, the top surface of the semiconductor body having a first zone and a second zone lateral to each other orthogonally to the first axis, the conductive layer having a respective top surface which is opposite to the semiconductor body along the first axis and is made of platinum;
b) forming on the conductive layer a first passivating layer made of silicon oxynitride (SiON), silicon nitride (SiN), or silicon oxide (SiO);
c) removing a part of the first passivating layer that is superimposed along the first axis on the second zone of the top surface of the semiconductor body, wherein the part of the first passivating layer that is superimposed along the first axis on the first zone of the top surface of the semiconductor body defines a first passivation sub-region of a passivation region of the MEMS device;
d) removing a part of the conductive layer that is superimposed along the first axis on the second zone of the top surface of the semiconductor body, wherein the part of the conductive layer that is superimposed along the first axis on the first zone of the top surface of the semiconductor body and that extends under the first passivation sub-region along the first axis defines a first conductive region of the MEMS device; and
e) forming, on the first passivation sub-region and on the second zone of the top surface of the semiconductor body, a second passivating layer made of silicon oxynitride (SiON), silicon nitride (SiN), or silicon oxide (SiO) that defines a second passivation sub-region of the passivation region,
wherein the passivation region comprises a first portion extending on the second zone of the top surface of the semiconductor body, and a second portion extending on the first conductive region, the first portion having a first thickness along the first axis and the second portion having a second thickness along the first axis, the second thickness being greater than the first thickness.

10. The method according to claim 9, wherein the step d) of removing the part of the conductive layer that is superimposed along the first axis on the second zone of the top surface of the semiconductor body comprises the step of:
d1) performing an etching on the conductive layer using the first passivation sub-region as a mask for the etching.

11. The method according to claim 9, wherein the step c) of removing the part of the first passivating layer that is superimposed along the first axis on the second zone of the top surface of the semiconductor body comprises:
c1) forming a lithographic mask on the first passivating layer, the lithographic mask covering a zone of the first passivating layer that extends along the first axis on the first zone of the top surface of the semiconductor body and exposing a zone of the first passivating layer that extends along the first axis on the second zone of the top surface of the semiconductor body; and
c2) performing an etching on the first passivating layer through the lithographic mask.

12. The method according to claim 10, further comprising, between step c2) and step d) the step of removing the lithographic mask from the first passivation sub-region.

13. The method according to claim 10, further comprising, between step d) and step e), the step of removing the lithographic mask from the first passivation sub-region.

14. The method according to claim 9, further comprising, between step a) and step b), the steps of:
forming on part of the conductive layer a first piezoelectric region of piezoelectric material, the first piezoelectric region being superimposed along the first axis on part of the first zone of the top surface of the semiconductor body; and
forming on the first piezoelectric region a second conductive region of conductive material;
wherein step b) comprises forming the first passivating layer also on the second conductive region; and
wherein the first conductive region, the first piezoelectric region and the second conductive region define a first piezoelectric structure of a piezoelectric stack of the device.

15. The method according to claim 97:
wherein the semiconductor body comprises a semiconductive body region made of semiconductor material, and an insulating body region made of passivating material and extending on the semiconductive body region along the first axis;
wherein step c) comprises defining a plurality of said first passivation sub-regions, lateral to each other and at a distance from each other orthogonal to the first axis;
wherein step d) comprises defining a plurality of said first conductive regions, one for each first passivation sub-region; and
wherein step e) comprises forming the second passivating layer on each first passivation sub-region.
